(19) United States
(12) Patent Application Publication
(10) Pub. No.: US 2025/0066920 A1
(43) Pub. Date: Feb. 27, 2025

(54) SUBSTRATE PROCESSING APPARATUS

(71) Applicant: EUGENE TECHNOLOGY CO., LTD., Yongin-si (KR)

(72) Inventors: In Soo SON, Hwaseong-si (KR); Chang Hun SHIN, Icheon-si (KR); Chan Yong PARK, Icheon-si (KR); Deog Hwan KIM, Yongin-si (KR); Jae Jun JUNG, Seoul (KR); Si Won RYU, Yongin-si (KR); Chang Min PARK, Seoul (KR); Jae Sun KIM, Seoul (KR); Ki Hoon KIM, Suwon-si (KR); Jong Hoon KIM, Hwaseong-si (KR)

(21) Appl. No.: 18/416,864

(22) Filed: Jan. 18, 2024

(30) Foreign Application Priority Data
Aug. 22, 2023 (KR) 10-2023-0110040

(51) Int. Cl. C23C 16/52; C23C 16/34; C23C 16/44; H01L 21/67

(52) U.S. Cl. CPC C23C 16/52; C23C 16/34; C23C 16/4405; H01L 21/67109

(57) ABSTRACT

Provided is a substrate processing apparatus, more particularly, a substrate processing apparatus capable of suppressing an generation of process by-products in a substrate processing process. A substrate processing apparatus includes a chamber part configured to provide an inner space in which a substrate is processed, a gas supply part configured to supply a process gas to the inner space, a substrate support configured to support the substrate, a heating liner provided inside the chamber part to at least partially surround the inner space, and a heating part configured to heat the heating liner.

### CROSS-REFERENCE TO RELATED APPLICATION

This application claims priority to Korean Patent Application No. 10-2023-0110040 filed on Aug. 22, 2023 and all the benefits accruing therefrom under 35 U.S.C. § 119, the contents of which are incorporated by reference in their entirety.

### BACKGROUND

The present disclosure relates to a substrate processing apparatus, and more particularly, to a substrate processing apparatus capable of suppressing a generation of process by-products in a substrate processing process.

In general, semiconductor elements are manufactured by depositing various materials in the form of a thin film on a substrate to pattern the deposited thin film. For this, several stages of different processing processes such as a deposition process, an etching process, a cleaning process and a drying process are performed.

If a process gas used during the substrate processing process for manufacturing a semiconductor element is consumed to remain on the substrate processing process, by-products generated during the substrate processing process may be generated to remain.

The by-products generated during the substrate processing process may cause contamination of a chamber to cause various limitations in semiconductor element manufacturing, and thus, so in-situ cleaning for removing impurities using a cleaning gas containing fluorine (F) atoms may be performed, or if a general cleaning gas is not used, a process of removing reactants may be carried out by introducing another reactive gas into a chamber to cause a reaction. For example, in the case of by-products containing chlorine (Cl) atoms, it is not easy to remove the by-products with the general cleaning gas, and the by-products may be removed by introducing H₂O gas (water vapor) into the chamber and reacting with HCl. However, if the cleaning gas or other reactive gas that replaces the cleaning gas is introduced into the chamber, the inside of the chamber may be contaminated by the gases, or if discharged outside the chamber, new limitations such as environmental pollution, equipment corrosion, and safety accidents may occur.

In accordance with the related art, an inert gas has been supplied into the chamber for a long time before the inside of the chamber is opened to remove the by-products remaining the chamber. However, when removing the by-products inside the chamber by supplying an inert gas, there is a limitation that a working time becomes longer. Thus, while the by-products present inside the chamber are removed, the substrate processing process may not be performed inside the chamber, which may significantly reduce efficiency of use of the substrate processing apparatus.

Thus, there is a continued need for technology that is capable of suppressing the generation of the by-products of the substrate processing process without introducing a reactive gas such as the cleaning gas into the chamber or prolonging the work time.

### SUMMARY

The present disclosure provides a substrate processing apparatus that is capable of suppressing generation of by-products in a substrate processing process using a heating liner provided inside a chamber.

In accordance with an exemplary embodiment, a substrate processing apparatus includes: a chamber part configured to provide an inner space in which a substrate is processed; a gas supply part configured to supply a process gas to the inner space; a substrate support configured to support the substrate; a heating liner provided inside the chamber part to at least partially surround the inner space; and a heating part configured to heat the heating liner.

The heating liner may be provided to be at least partially spaced apart from an inner surface of the chamber part.

The heating liner may include: a sidewall part extending at least partially along an inner wall of the chamber part; a bottom part bent inward from a lower end of the sidewall part to extend at least partially along a bottom surface of the chamber part; and a space maintenance part provided on an outer surface of the sidewall part or the bottom part to maintain a distance from an inner surface of the chamber part.

The space maintenance part may include: a protrusion provided on an outer surface of the bottom part; or a fixing pin coupled to the inner wall of the chamber part to support and fix the outer surface of the sidewall part.

The heating part may include a linear heat generating element and a planar heat generating element extending an outer circumferential surface of the heating liner.

A temperature of the heating liner may be higher than that of an outer surface of the chamber part by the heating part and be maintained to be lower than a temperature of the substrate support.

The substrate processing apparatus may further include a cylindrical inner liner provided between the heating liner and the substrate support and having a height lower than that of the heating liner, wherein the heating liner may be provided with a first exhaust port configured to exhaust the inner space.

The substrate processing apparatus may further include a cylindrical outer liner provided between the inner liner and the heating liner, wherein the outer liner may be provided with a second exhaust port that communicates with the first exhaust port to exhaust the inner space.

The outer liner may have an upper inner diameter less than a lower inner diameter thereof.

The substrate support may include: a heater configured to heat the substrate; a heater support flange connected to a lower end of the heater to support the heater; and a passage which is provided in the heater support flange and through which a temperature control fluid flows.

The substrate processing apparatus may further include: a bellows connected between a portion of the chamber part and the heater support flange; and an elastic member provided between the bellows and the heater support flange.

The temperature control fluid may be supplied at a temperature higher than room temperature.

The substrate support may include: a clamp configured to fix a lower end of the heater to the heater support flange; and a cover member provided at least partially on the clamp to cover the clamp.

The substrate support may further include a plate-shaped thermal choke part provided between the clamp and the cover member to suppress heat transfer.

The chamber part may have a hole in a central portion of a bottom surface of the chamber part so that a portion of the substrate support passes to move through the hole, and the substrate processing apparatus may further include a purge gas supply part configured to supply a purge gas so that the purge gas is ejected through a gap between the hole and the cover member.

The purge gas may be provided at a temperature higher than room temperature.

### BRIEF DESCRIPTION OF THE DRAWINGS

Exemplary embodiments can be understood in more detail from the following description taken in conjunction with the accompanying drawings, in which:

FIG. 1 is a cross-sectional view of a substrate processing apparatus in accordance with an exemplary embodiment; and

FIG. 2 is a perspective view of a heating liner in accordance with an exemplary embodiment.

### DETAILED DESCRIPTION OF EMBODIMENTS

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

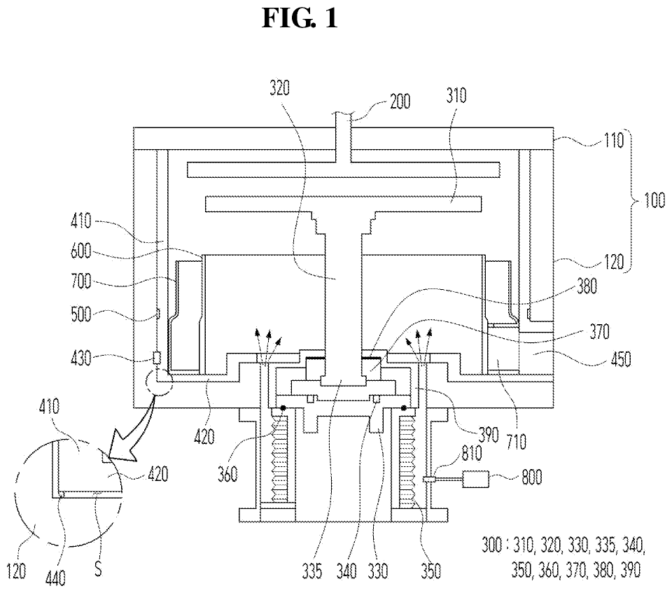

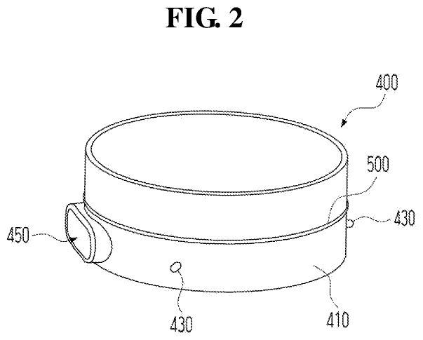

FIG. 1 is a cross-sectional view of a substrate processing apparatus in accordance with an exemplary embodiment, and FIG. 2 is a perspective view of a heating liner in accordance with an exemplary embodiment.

Referring to FIGS. 1 and 2, a substrate processing apparatus in accordance with an exemplary embodiment may include a chamber part 100 that provides an inner space for processing a substrate, a gas supply part 200 that supplies a process gas to the inner space, a substrate support 300 that supports a substrate, a heating liner 400 provided inside the chamber part 100 to at least partially surround the inner space, and a heating part 500 that heats the heating liner.

The substrate processing apparatus may be an apparatus that processes several different processing processes such as a deposition process, an etching process, a cleaning process, and a drying process, which are required to manufacture semiconductor elements. For example, the substrate processing apparatus may be a thin film deposition that processes the deposition process to form a titanium nitride (TiN) thin film by reacting process gases of titanium tetrachloride (TiCl₄) and ammonia (NH₃).

The chamber part 100 provides a processing space, which is an inner space in which a processing process is performed on a substrate. The inner space may be maintained in a vacuum state by a vacuum pump connected through an exhaust port and may be a space in which the processing process for the substrate is performed after the process gas is introduced to form a predetermined atmosphere after being exhausted to a high degree of vacuum. The chamber part 100 may include a chamber body 120 surrounding the inner space and a chamber lid 110 covering an open upper portion of the chamber body 120, and an independent inner space that is distinguished from an external environment may be defined by the chamber body 120 and the chamber lid 110. The chamber body 120 may have a sidewall and a bottom surface, each of which has a cylindrical shape for structural stability. The sidewall may be provided with an entrance through which the substrate is loaded and unloaded and an exhaust port for exhausting the inner space.

The gas supply part 200 may supply various process gases required for the substrate processing to the inner space inside the chamber part 100. The process gases may be in gaseous or vapor form depending on raw materials. The gas supply part 200 may be a shower head type that forms a process gas supply surface to face a substrate support surface of the substrate support 300 so as to uniformly supply the process gas to the substrate and may include an electrode to which an RF power and/or DC power for generating plasma inside or outside the shower head is connected to be applied. The gas supply part 200 may need not be limited to the shower head type and may be an injector type that injects the process gas in various directions toward the inner space.

The substrate support 300 may receive and seat a substrate input from the outside and stably support the substrate during the substrate processing process. If necessary, the substrate support 300 may include a heater that heats the substrate to the substrate processing temperature or may include an electrostatic chuck or vacuum chuck that supports the substrate more stably, and components such as the heater, electrostatic chuck, and the like may be stacked to constitute the substrate support 300 having various functions.

The heating liner 400 may be provided inside the chamber part 100 to at least partially surround the inner space in which the substrate is processed.

In general, a liner may be provided inside a chamber in a plate shape to surround the substrate processing space, thereby preventing process gases or their reaction products from being in direct contact with the inner surface of the chamber during the substrate processing process so as to protect the inside of the chamber. If necessary, the liner may be detached from the inside of the chamber to undergo a cleaning process outside the chamber.

In the case of a deposition device for depositing a thin film, the process gas supplied by the gas supply part 200 may be decomposed to react by heat energy supplied by a heating part 500 or the like within the surface of the substrate or the inner space of the chamber 100, thereby deposit a thin film having predetermined components and composition. However, if the energy required for the decomposition or synthesis reaction of the process gas is not sufficiently supplied, an incomplete decomposition reaction or synthesis reaction of the process gas may occur to preventing the deposition of the required thin film, thereby generating incomplete intermediate products or reaction by-products. Particularly, the incomplete intermediate products or reaction by-products generated due to the insufficient energy may exist in the gas phase (or vapor phase), and when the incomplete intermediate products or reaction by-products reach the inner surface of the chamber or a surface of the liner, which has a low temperature, the incomplete intermediate products or reaction by-products may be changed from a gas phase to a solid phase and then be attached or deposited on the inner surface of the chamber or the surface of the liner. The solid intermediate products or reaction by-products that are attached to the inner surface of the chamber or the liner may not only contaminate the inside of the chamber or the liner, but also fall down from the inner surface of the chamber or the liner to generate particles and then may be attached again to the surface of the substrate to cause fatal limitations in final products such as semiconductor elements manufactured through the substrate processing process.

In order to remove the intermediate products or reaction by-products attached to the inner surface of the chamber or the surface of the liner, the cleaning gas may be introduced into the chamber to perform the in-situ cleaning process, thereby cleaning the inside of the chamber. However, the intermediate products or reaction by-products may not be removed by general cleaning gases containing a fluorine (F) element, or cleaning by-products may be generated to act as a new source of contamination. For example, in the case of the intermediate products or reaction by-products containing the chlorine (Cl) element, the intermediate products or reaction by-products may not be removed by the cleaning gas containing the fluorine (F) element, and thus, a method of removing HCl generated by reaction using an H₂O-based cleaning gas may be adopted. The chlorine (Cl) element may be converted into HCl and then removed, but HCl that is a strong acid, may have a limitation in which components constituting the chamber corrodes or causes environment pollution when discharged to the outside.

To fundamentally solve this limitation, the temperature of the chamber may be maintained relatively high to prevent the intermediate products or reaction by-products from being attached to the inner surface of the chamber or the surface of the liner. However, when the chamber is maintained at a relatively high temperature, a temperature of the entire substrate processing apparatus may increase to cause a limitation in stable control of components attached to the chamber and a limitation in safety of workers using the substrate processing apparatus.

In the present disclosure, the heating liner 400 provided inside the chamber part 100 to at least partially surround the inner space in which the substrate is processed may be heated using the heating part 500 so as to be maintained at a temperature higher than a predetermined temperature (for example, room temperature), thereby preventing the intermediate products or reaction by-products that are by-products of the substrate processing process existing in the inner space from being attached to the surface of the heating liner 400. In addition, since the inner surface of the chamber part is protected by the heating liner 400, the intermediate products or reaction by-products may be prevented from being attached to the inner surface of the chamber part 100.

The heating liner 400 heated by the heating part 500 may be provided to be adjacent to the inner surface of the chamber part 100. Thus, although the heating liner 400 has a temperature less than that of the internal space so as to be maintained at a relatively high temperature in order to supply the high energy required for the process reaction, the heating liner 400 may be maintained at a predetermined temperature so that the process by-products are not solidified to be attached to the surface of the heating liner 400 surrounding the inner space and are exhausted while being maintained in the gas phase. Thus, since the process by-products are not attached to the inner surface of the chamber part 100 protected by the heating liner 400, the chamber portion 100 may not need to be maintained at a high temperature, but be maintained to a temperature less than that of the heating liner 400. Thus, the components attached to the chamber may be used stably, and the limitation related to worker safety may be eliminated.

The heating liner 400 has to be provided inside the chamber part 100 to at least partially surround the inner space and thus may be provided in a plate shape so as to be deformed in shape, and the heating liner 400 may be made of a metal (e.g., aluminum or aluminum alloy) so that the heat energy provided by the heating part 500 is quickly transferred to be maintained at a uniform temperature. In addition, the heating liner 400 needs to have corrosion resistance against the process gases and the reaction by-products.

The heating part 500 may be controlled to heat the heating liner 400 to a temperature determined in accordance with the type of process gas and process by-products. Since the process gas and process by-products have a different temperature at which the process gas and process by-products are not attached to the surface of the heating liner 400, but are exhausted, a temperature measuring part that measures a temperature of the heating liner 400 so that the temperature of the heating liner 400 is controlled differently depending on the process gas and process reaction by-products, and a control part that controls the heating part 500 using the measured temperature may be further provided. The heating liner 400 may be heated by receiving heat from the substrate support 300 for heating the substrate to the substrate processing temperature. However, in this case, the temperature of the heating liner 400 may not be adjusted depending on the type of process gas and process reaction by-products to prevent process reaction by-products from being generated, thereby effectively preventing the process reaction by-products from being attached to the surface of the heating liner 400.

The process gas supplied to the inner space of the chamber part 100 may be selected in various manners depending on the substrate processing process. The process gas required for the substrate processing process may include chlorine (Cl). When the process gas containing chlorine is used in the substrate processing process, the process by-products containing chlorine may be attached to the inner surface of the chamber or the line surface below a predetermined temperature. There is no effective cleaning gas for the in-situ cleaning of the process by-products including chlorine, and even if being cleaned, it may have many limitations such as environmental pollution or stability. In the present disclosure, the heating liner 400 that at least partially surrounds the internal space of the chamber part 100 may be heated to be maintained at a temperature higher than a predetermined temperature, thereby preventing the process by-products including chlorine existing in the internal space from being discharged without being attached to the surface of the heating liner 400.

The process gas including chlorine (Cl) may be a gas or vapor phase of chloride such as titanium tetrachloride (TiCl₄) or aluminum trichloride (AlCl₃), which is used as a raw material to form a nitride thin film. For example, the substrate processing apparatus in accordance with an exemplary embodiment may allow titanium tetrachloride (TiCl₄) and ammonia (NH₃) supplied to the inner space of the chamber part 100 to react with each other at a process temperature of approximately 450° C. to approximately 650° C. as shown in the reaction equation below, thereby perform the deposition process for forming a titanium nitride (TiN) thin film.

In addition to the reaction products generated in the reaction to form the titanium nitride thin film, various intermediate products or process by-products such as TiCl₄·5NH₃, TiClN, and NH₄Cl may be generated depending on the temperature. Particularly, NH4Cl that is a process by-product may be attached to an inner wall of the chamber or the surface of the liner in the form of white powder at a temperature of approximately 150° C.

In the present disclosure, when the temperature of the heating liner 400 is maintained at approximately 150° C. to approximately 250° C. using the heating part 500, NH4Cl may be discharged in the form of the white powder without being attached to the surface of the heating liner 400 to prevent the inside of the chamber from being contaminated by the process by-products.

The heating liner 400 may be provided to be at least partially spaced apart from the inner surface of the chamber part 100.

For the stable control of the various components attached to the chamber part 100 and the safety of the workers, the chamber part 100 may need to be maintained at a temperature lower than approximately 100° C. When the heating liner 400 is maintained at a relatively high temperature (e.g., approximately 150° C. to approximately 250° C.) to suppress the attachment of the process by-products, if the chamber part 100 is in contact with the heating liner 400, the temperature of the chamber part 100 may increase due to the heating liner 400, and the heating liner 400 may lose the heat to the chamber part 100, and thus, it may be difficult to maintain a stable temperature. Thus, the inner surfaces of the heating liner 400 and the chamber part 100 may not be in entirely contact with each other, but may be at least partially spaced apart from each other. In general, since the inside of the chamber part 100 is maintained in a vacuum state during the substrate processing process, if a spaced space exists between the heating liner 400 and the chamber part 100, the heating liner 400 and the chamber part 100 may be effectively insulated from each other by the vacuum, and each of the heating liner 400 and the chamber part 100 may be independently maintained at a predetermined temperature.

The heating liner 400 may include a sidewall part 410 extending at least partially along the inner wall of the chamber part 100, a bottom part 420 that is bent inward at a lower end of the sidewall part 410 to extend at least partially along a bottom surface of the chamber part 100, and space maintenance parts 430 and 440 disposed on an outer surface of the sidewall part 410 or the bottom part 420 to maintain a distance from an inner surface of the chamber part 100.

In general, after the process gas supplied to the inner space of the chamber part 100 is consumed on the substrate on which the process is performed, a residual process gas and process reaction by-products may not remain in a space on the substrate, but be exhausted to a lower side of the substrate support 300. The exhaust port that exhausts the inner space of the chamber part 100 may be provided at the lower side of the bottom or side surface of the chamber part 100. In this case, the residual process gas and process by-products existing in the space on the substrate or in the space adjacent to the substrate support 300 may be maintained at the process temperature, but the temperature may decreases in a process of flowing to the lower side of the substrate support 300 to perform the exhaustion, and thus, possibility of the process by-products to be attached to the bottom or side surfaces of the chamber part 100 may increase.

To solve this limitation, the heating liner 400 heated to the predetermined temperature of the present disclosure may include not only the sidewall part 410 extending along the inner wall of the chamber part 100, but also the bottom part 420 extending along the bottom surface of the chamber part 100 in which the possibility of the process by-products to be attached is high. Since the sidewall part 410 and the bottom part 420 extend along the inner wall and the bottom surface of the chamber part 100, the space maintenance parts 430 and 440 that maintains a spaced distance from the inner surface of the chamber part 100 may be further provided on at least one outer surface of the sidewall part and the bottom part 420 so that the sidewall part 410 and the bottom part 420 are not in contact with the inner wall and the bottom surface of the chamber part 100.

The space maintenance part may be a protrusion 440 provided on an outer surface of the bottom part or a fixing pin 430 that is coupled to the inner wall of the chamber part to support and fix an outer surface of the sidewall part.

The heating liner 400 provided in the inner space of the chamber part 100 may need to be firmly supported inside the chamber part 100 so as to withstand its own weight. When provided on the outer surface of the bottom part 440 and supported on the bottom surface of the chamber part 100 by the plurality of protrusions 440 having a certain height, the bottom surface of the chamber part 100 may stably support the own weight of the heating liner 400. The plurality of protrusions 440 may be at least three for the stable support and may be spaced apart from each other at the same angular interval (in the case of the three protrusions, the plurality of protrusions are spaced apart from each other at an equal interval of approximately 120°).

The fixing pin 430 may be coupled to the inner wall of the chamber part 100 or an outer circumferential surface of the sidewall part 410 to support and fix the outer circumferential surface of the sidewall part 410 to the inner wall of the chamber part 100. When the heating liner 400 is provided with the plurality of protrusions 440, the plurality of protrusions 440 may support the own weight of the heating liner 400, and thus, the fixing pin 430 may not need to support the heating liner 400 in a vertical direction, and it may be sufficient to determine a position of the heating liner 400 in a horizontal direction so as to support the heating liner 400.

Like the protrusion 440, the plurality of fixing pins 430 may be provided at equal angular intervals to stably support the heating liner 400 in the horizontal direction. The plurality of protrusions 440 and the plurality of fixing pins 430 may be provided in the same number and may be provided at azimuth positions that cross each other when viewed from the top for more stable support.

The plurality of fixing pins 430 may be partially inserted and coupled to the inner wall or sidewall part 410 of the chamber part 100, and an insertion length may be adjusted to adjust a height protruding from the inner wall or sidewall part 410 of the chamber part 100, thereby adjusting a horizontal position of the heating liner 400 supported by being in contact with the plurality of fixing pins 430. A screw thread may be disposed on an outer surface of the fixing pin 430, the inner wall of the chamber part 100, into which the fixing pin 430 is inserted, and/or an inner surface of a groove of the sidewall part 410 so as to be coupled while adjusting an insertion length of the fixing pin 430.

The heating part 500 may be a linear heat generating element or a planar heat generating element extending along an outer circumferential surface of the heating liner 400.

The heating liner 400 has to be uniformly maintained at a predetermined temperature to effectively prevent the process by-products from being attached to the surface. However, if an area having a temperature less than the predetermined temperature exists locally, the process by-products may be generated on the low-temperature area. Since the heating liner 400 extends along the inner wall or the bottom surface of the chamber part 100, when the heating part 500 may be provided only at one side of the heating liner 400, and thus, it may be difficult to maintain the heating liner 400 at a uniform temperature because a heat transfer length increases. In the present disclosure, the heating part 500 may be constituted by the linear heat generating element or the planar heat generating element extending along the outer circumferential surface of the heating liner 400 to maintain a uniform temperature throughout the heating liner 400. As illustrated in FIG. 2, the linear heat generating element extending along the outer circumferential surface of the sidewall part 410 may be provided. If the height of the sidewall part 410 is high, the linear heat generating element extending along the outer circumferential surface of the sidewall part 410 may be provided in plurality, which are arranged side by side, or the planar heat generating element extending along the outer circumferential surface of the sidewall part 410 may be provided. Since the heating liner 400 is closest to the substrate support 310, which maintains the process temperature during the substrate processing process, in the horizontal direction so that the heat transfer is relatively active, the height of the linear heat generating element or the planar heat generating element extending along the outer circumferential surface of the heating liner 400 may be less than that of the substrate support plate 310 disposed during the substrate processing process.

The heating part 500 may further include a linear heat generating element or a planar heat generating element, which extends along the outer circumferential surface of the bottom part 420 in the form of a concentric circle centered on a center of the bottom part 420 to heat the bottom part 420 to be more precisely maintained at a predetermined temperature.

In addition, when the heating part 500 is provided to protrude from an inner circumferential surface of the plate-shaped heating liner 400, the residual process gas and the reaction by-products may be attached to a groove or concave portion between the inner circumferential surface of the heating liner 400 and the heating part 500. On the other hand, in the present disclosure, the heating part 500 may be provided on the outer circumferential surface of the heating liner 400, and thus, the inner circumferential surface of the heating liner 400 may be maintained as a flat surface to prevent the residual process gas and the reaction by-products from being easily attached.

Due to the structure of the heating liner 400 as described above, a temperature of the heating liner 400 heated by the heating part 500 may be greater than that of the outer surface of the chamber part 100 and be less than that of the substrate support 300. The temperature of the substrate support 300 may have to be maintained at a relatively high temperature so that the substrate reaches the processing temperature, and the temperature of the outer surface of the chamber part 100 may have to be maintained at a temperature less than approximately 100° C. to ensure the stability of components mounted in the chamber part 100 and the safety of the workers. On the other hand, the temperature of the heating liner 400 may be controlled independently of the temperature of each of the substrate support 300 and the chamber part 100 so that the temperature of the heating liner 400 is maintained lower than the process temperature and higher than the temperature of the outer surface of the chamber part 10 to prevent the process by-products from being attached.

The substrate processing apparatus in accordance with an exemplary embodiment may further include a cylindrical inner liner 600 provided between the heating liner 400 and the substrate support 300 and having a height lower than that of the heating liner 400, and the heating liner 400 may be provided with a first exhaust port 450 that exhausts the inner space.

The substrate support 300 may include a substrate support plate 310 that provides a substrate support surface for supporting the substrate, and a shaft 320 that supports the substrate support plate 310. Each of the substrate support plate 310 and the shaft 320 may have a “T” shape. When the process gas is uniformly supplied to the substrate, after the reaction occurs on the surface of the substrate or in the space on the substrate, the residual process gas and the process by-products may pass through an edge of the substrate support plate 310 to move to a lower side. Since the shaft 320 has a diameter less than that of the substrate support plate 310, the process by-products, etc. may pass through a narrow space between the substrate support plate 310 and the chamber part (or heating liner) and then be exhausted through the exhaust port provided at the lower side of the chamber part 100 after passing through a wide space between the shaft 320 and the chamber part (or heating liner). That is, the process by-products, etc. may be spread widely as the process by-products move from the narrow space to the wide space, and in particular, move across the inner space of the chamber part 100 toward the exhaust port provided at one lower side of the chamber part 100. In this case, the process by-products that are spread widely to move across the inner space may be attached to the shaft 320 or a central lower side of the chamber part 100.

In the present disclosure, to guide the process by-products, etc. so that the process by-products flow into a space adjacent to the heating liner 400, which is heated to be maintained at a predetermined temperature, without moving across the space inside the chamber, the cylindrical inner liner 600 having a height less than that of the heating liner 400 may be provided between the heating liner 400 and the substrate support 300. To prevent the process by-products, etc. from flowing into the inner space of the inner liner 600, the inner liner 600 may have a cylindrical shape without a through-hole, etc., and when the heating liner 400 is provided with the first exhaust port 450 that exhausts the inner space, the process by-products, etc. may flow into the space between the heating liner 400 and the inner liner 600 and then be exhausted to the outside through the first exhaust port 450.

Since the inner liner 600 is disposed closer to the substrate support plate 310 than the heating liner 600, the inner liner 600 may receive heat from the substrate support plate 310 and thus may be maintained at a relatively high temperature, and for more precise temperature control, the linear heat generation element or the planar heat generation element extending along the inner circumferential surface of the inner liner 600 may be provided.

The inner liner 600 may be disposed on the bottom part 420 of the heating liner 400, and a lower end of the inner liner 600 may be inserted and supported so that the inner liner 600 is disposed at a correct position, and the heat transfer with the heating liner 400 occurs more effectively.

The substrate processing apparatus in accordance with an exemplary embodiment may further include a cylindrical outer liner 700 provided between the inner liner 600 and the heating liner 400. The outer liner 700 may be provided with a second exhaust port 710 that communicates with the first exhaust port 450 to exhaust the inner space. Due to this structure, the process by-products, etc. may be guided into a space between the inner liner 600 and the outer liner 700 and then be exhausted the outside through the first exhaust port 450 via the second exhaust port 710, and thus, a path through which the process by-products, etc. flow to be exhausted may be controlled more precisely.

The outer liner 700 may have an upper inner diameter less than a lower inner diameter. In this case, an interval between the outer liner 700 and the inner liner 600 may be narrowed at an upper side than at a lower side. In order for the process by-products, etc. to be exhausted, the process by-products may flow to the lower side of the chamber part 100 to pass through a narrow gap (or narrow cross-section) and then pass through a wide gap (or wide cross-section), and thus, the process by-products, etc. may be exhausted quickly at a faster rate.

In addition, when the lower inner diameter of the outer liner 700 increases, it may be possible to get closer to or be in contact with the heating liner 400, which is maintained at a predetermined temperature at the lower side, and the temperature of the outer liner 700 may also be controlled by receiving the heat transfer from the heating liner 400. In addition, the outer liner 700 may be provided with an extension that is bent inward from the lower portion to extend, and the extension may be provided on the bottom part 420 of the heating liner so as to be stably supported to stand up on its own, and thus, thermal contact may be achieved more effectively.

If a separate cleaning process is required due to long-term use, the easily detachable inner liner 600 and outer liner 700 may be removed and then mounted on the heating liner 400 after the cleaning.

The substrate support 300 may include heaters 310 and 320 that heat the substrate, a heater support flange 330 connected to a lower end of the heaters 310 and 320, and a passage 340 which is provided in the heater support flange 330 and through which a temperature control fluid flows.

The heaters 310 and 320 may include the substrate support plate 310 that provides a substrate support surface for supporting the substrate to supply heat energy to the substrate and the shaft 320 that supports the substrate support plate 310. The substrate support plate 310 may further include an electrostatic chuck or a vacuum chuck for chucking the substrate as well as the heating plate.

To heat the substrate to the process temperature, the heat generated from the heating plate provided on the substrate support plate 310 may be transferred through the shaft 320 to the heater support flange 330, and thus, the heat support flange 330 may also increase to a high temperature. If the heater support flange 330 increases to a high temperature, it may cause thermal damage to surrounding components and adversely affect the safety of the workers, and thus, the temperature control fluid (e.g., water) may flow to the passage 340 provided in the heater support flange 330 to control a temperature of the heater support flange 330.

Since it is necessary to adjust the height of the substrate support 300 in accordance with the process performed in the substrate processing apparatus, the substrate processing apparatus may further include an elevation part (not shown) that elevates the substrate support 300. While the substrate support 300 is elevated, a sealing state with the chamber part 100 may be changed to cause leakage of the process gas or atmosphere. To prevent this phenomenon, the substrate processing apparatus may further include a bellows 350 connected between a portion of the chamber part 100 and the heater support flange 330 and an elastic member 360 provided between the bellows 350 and the heater support flange 330.

That is, even if the substrate support 300 is elevated by the bellows 350 connected between a portion of the fixed chamber part 100 and the heater support flange 330 that is elevated, the vacuum state may be stably maintained, and the elastic member 360 such as an O-ring may be disposed between the bellows 350 and the heat support flange 330 to prevent a gas from leaking through a connected portion between the bellows 350 and the heat support flange 330.

When the temperature of the heater support flange 330 increases to a high temperature, the elastic member 360 may be deteriorated by the heat, resulting in a decrease in sealing property, and thus, the temperature control fluid may flow through the passage 340 to lower the temperature of the heat support flange 330. On the other hand, if the temperature control fluid (e.g., room temperature coolant) having a too low temperature flows through the passage 340, the heater support flange 330 and the surrounding components (e.g., a plate adapter 335, a clamp 370, cover member 390, etc.) may become too low. If the temperature of the heater support flange 300 and the surrounding components becomes too low, the process by-products may be attached to the surface to cause the contamination, and thus, the temperature control fluid flowing into the passage 340 may be supplied at a temperature higher than room temperature so that the process by-products are prevented from being solidified and attached to the surfaces of the heater support flange 300 and the surrounding components. Here, since the temperature control fluid needs to cool the heater support flange 330, the temperature may be lower than the temperature of the heating liner 400.

The substrate support 300 may further include a clamp 370 that fixes a lower end of each of the heaters 310 and 320 to the heater support flange 330, and a cover member 390 that is at least partially provided on the clamp 370 to cover the clamp 370.

The clamp 370 may clamp the lower end of the shaft 320 to the heater support flange 330 to fix and support the shaft 320. The clamp 370 and the heater support flange 330 may be firmly fixed using bolts. Here, a plate adapter 335 may be further provided between the clamp 370 and the heater support flange 330 to improve adhesion. To stably support the lower end of the heater, structures such as the heater support flange 300, the clamp 370, and the plate adapter 335 may be required. When the process by-products, etc. approach the structures, the process by-products may be easily attached between the complex structure to which each of the structures is connected. Therefore, the cover member 390 may be at least partially provided on the clamp 370 to cover the structures such as the heat support flange 300, the clamp 370, and the plate adapter 335 so as to prevent the structures such as the heat support flange 300, the clamp 370, and the plate adapter 335 from being exposed to the process by-products, thereby protecting the structures against the process by-products.

In addition, the substrate support 300 may further include a plate-shaped thermal choke part 380 provided between the clamp 370 and the cover member 390 to suppress the heat transfer.

The clamp 370, which clamps and supports the lower end of each of the heaters 310 and 320, may be in contact with the lower end of each of the heaters 310 and 320 and thus may receive the heat from the heaters 310 and 320 so as to be heated to a relatively high temperature. When the clamp 370 is heated to the high temperature, heat may be transferred at least partially to the cover member 390 provided on the clamp 370 and thus be heated to a similarly high temperature. When the residual process gas or the process by-products reach the cover member 390 heated to the high temperature, the thermal energy required for the process reaction may be supplied to be deposited on the surface of the cover member 390 in the form of a thin film, unlike the case in which the residual process gas or the process by-products are simply solidified to be attached to the surface of the heating liner 400. Therefore, to prevent the cover member 390 from rising to a high temperature, the thermal choke part 380 having an insulating function may be inserted between the clamp 370 and the cover member 390 to suppress the heat transfer. The thermal choke part 380 may not need to be completely insulated, but have lower thermal conductivity than each of the clamp 370 and the cover member 340 to suppress the heat transfer between the clamp 370 and the cover member 390. For example, the thermal choke part 380 may be made of an engineering plastic material having low thermal conductivity.

The chamber part 100 may be provided with a hole in a center of the bottom surface of the chamber body 120, through which a portion of the substrate support 300 moves, and may further include a purge gas supply part 800 that supplies a purge gas so that the purge gas is ejected through a gap between the hole and the cover member 390.

The substrate support 300 needs to elevate the substrate to a predetermined height in accordance with substrate processing process conditions. The substrate support 300 may be elevated by driving force provided by the elevation part (not shown). To allow the heaters 310 and 320, each of which has a certain height, to be elevated, a portion of the substrate support 300 (e.g., the shaft 320) may have to move vertically through a central portion of the bottom surface of the chamber body 120. In order for the entire structure of the substrate support 300 to be provided inside the chamber part 100 so as to perform the ascending and descending, a volume of the chamber part 100 has to be too large. Therefore, in terms of space utilization, a portion of the substrate support 300 has to move vertically through the central portion of the bottom surface of the chamber body 120.

When the substrate support 300 is elevated, the cover member 390 constituting the substrate support 300 also moves through the hole defined in the central portion of the bottom surface of the chamber body 120. Here, a predetermined space between the cover member 390 and the hole may be required so that the cover member 390 does not interfere with an inner surface of the hole while the cover member 390 is elevated. When the residual process gases and the process by-products flow into a space between the cover member 390 and the hole, the process by-products may be attached or deposited in the spaced space between the inner surface of the hole, which is maintained at a relatively low temperature, and the cover member 390 adjacent thereto.

In the present disclosure, the purge gas supply part 800 may supply the purge gas to the space between the hole and the cover member 390 so that the purge gas is ejected from the space toward the inner space of the chamber part 100, thereby preventing the residual process gas and the process by-products from being introduced toward the spaced space between the cover member 390 and the hole and suppressing the attachment and deposition of the process by-products.

The chamber part 100 may include a chamber extension 130 extending outward from the hole defined in the central portion of the bottom surface of the chamber body 120. An inner space of the chamber extension 130 may communicate with the hole to provide a path along which a portion of the substrate support 300 is elevated. A lower end of the bellows 350 may be connected to a lower part of the chamber extension 130, and an upper end of the bellows 350 is connected to the heater support flange 330, and thus, while the substrate support 300 is elevated, the space between the inner surface of the extension 130 and the outer surface of the bellows 350 may be separated from atmospheric pressure and then may be maintained in the vacuum state. That is, the space between the inner surface of the chamber extension 130 and the outer surface of the bellows 350 may communicate with the space between the cover member 390 and the hole. When the purge gas supply part 800 supplies the purge gas to the space between the inner surface of the chamber extension 130 and the outer surface of the bellows 350 through a purge gas injection part passing through a sidewall of the chamber extension 130, the supplied purge gas may be ejected through the spaced space between the cover member 390 and the hole.

When the purge gas supplied from the purge gas supply part 800 has a low temperature, the purge gas may flow through the spaced space between the cover member 390 and the hole to decrease in a temperature of each of the cover member 390 and the hole and also decrease in temperature of the process by-products introduced into the vicinity of the spaced space between the cover member 390 and the hole, and thus, the process by-products may be attached to the cover member 390 and the hole or generate solid particles in the space. Therefore, in the present disclosure, the purge gas supply part 800 may include a purge gas heating block 810 that heats the purge gas before the purge gas is supplied into the chamber part 100 so that the purge gas is supplied at a temperature higher than room temperature. When the purge gas heated to the temperature higher than room temperature and lower than the temperature of the heating liner 400 is supplied, force injected into the space between the cover member 390 and the hole may prevent the process by-products from being introduced, and due to the high temperature of the purge gas, the process by-products may not be changed into the solid state, but remain into a gaseous state so that the process by-products are discharged to the outside without contaminating the inside of the chamber part 100.

In the substrate processing apparatus in accordance with the exemplary embodiment, the inside of the chamber part may be maintained at the predetermined temperature or more by using the heating liner provided to at least partially surround the inner space, in which the substrate processing process is performed, to exhaust the process by-products in the substrate processing process without being attached, thereby suppressing the contamination of the inside of the chamber 100. As a result, the substrate processing process may be continuously performed using the cleaning gas after the substrate processing process without the additional cleaning process such as the in-situ cleaning to improve the efficiency of use of the substrate processing apparatus.

Particularly, in the process of exhausting the process gases consumed in the inner space of the substrate, the by-products may be likely to be generated while passing through the area having the temperature less than the substrate processing temperature, and thus, the temperature of the heating liner provided at the lower height than the substrate support surface, on which the substrate support 300 supports the substrate, and the lower portion of the substrate support 300 may be maintained at the predetermined temperature or more to effectively suppress the attachment of the process by-products.

Furthermore, the inner liner 600 and/or the outer liner 700 may be provided inside the heating liner 400 to limit the path, along through the residual process gas or the process by-products are exhausted, to prevent the solid by-products from being indiscriminately attached inside the chamber part 100, thereby enabling the substrate processing apparatus to be easily maintained.

In the substrate processing apparatus in accordance with the exemplary embodiment, the inside of the chamber part may be maintained at the predetermined temperature or more by using the heating liner provided inside the chamber part of the substrate processing apparatus to at least partially surround the inner space, in which the substrate processing process is performed, to suppress the generation of the by-products in the substrate processing process, thereby suppressing the inside of the chamber from being contaminated. As a result, the substrate processing process may be continuously performed using the cleaning gas after the substrate processing process without the additional cleaning process such as the in-situ cleaning to improve the efficiency of use of the substrate processing apparatus.

Particularly, in the process of exhausting the process gases consumed in the inner space of the substrate, the by-products may be likely to be generated while passing through the area having the temperature less than the substrate processing temperature, and thus, the temperature of the heating liner provided at the lower height than the substrate support surface, on which the substrate support supports the substrate, and the lower portion of the substrate support may be maintained at the predetermined temperature or more to effectively suppress the generation of the process by-products.

Furthermore, the inner liner and/or the outer liner may be provided inside the heating liner to limit the path, along through the residual process gas or its by-products are exhausted, to prevent the solid by-products from being indiscriminately generated inside the chamber, thereby enabling the substrate processing apparatus to be easily maintained.

The term ‘˜on’ the above description includes direct contact and indirect contact at a position that is opposite to an upper and lower portion. It is also possible to locate not only the entire top surface or the entire bottom surface but also the partial top surface or the bottom surface, and it is used in the mean that it is opposed in position or contact directly to upper or bottom surface. In addition, terms such as ‘top’, ‘bottom’, ‘front end’, ‘rear end’, ‘upper portion’, ‘lower portion’, ‘upper end’, ‘lower end, etc. used in the above description are defined based on the drawings for convenience, the shape and location of each component are not limited by this term.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

What is claimed is:

1. A substrate processing apparatus comprising:
a chamber part configured to provide an inner space in which a substrate is processed;
a gas supply part configured to supply a process gas to the inner space;
a substrate support configured to support the substrate;
a heating liner provided inside the chamber part to at least partially surround the inner space; and
a heating part configured to heat the heating liner.

2. The substrate processing apparatus of claim 1, wherein the heating liner is provided to be at least partially spaced apart from an inner surface of the chamber part.

3. The substrate processing apparatus of claim 2, wherein the heating liner comprises:
a sidewall part extending at least partially along an inner wall of the chamber part;
a bottom part bent inward from a lower end of the sidewall part to extend at least partially along a bottom surface of the chamber part; and
a space maintenance part provided on an outer surface of the sidewall part or the bottom part to maintain a distance from an inner surface of the chamber part.

4. The substrate processing apparatus of claim 3, wherein the space maintenance part comprises:
a protrusion provided on an outer surface of the bottom part; or
a fixing pin coupled to the inner wall of the chamber part to support and fix the outer surface of the sidewall part.

5. The substrate processing apparatus of claim 1, wherein the heating part comprises a linear heat generating element and a planar heat generating element extending an outer circumferential surface of the heating liner.

6. The substrate processing apparatus of claim 1, wherein a temperature of the heating liner is higher than that of an outer surface of the chamber part by the heating part and is maintained to be lower than a temperature of the substrate support.

7. The substrate processing apparatus of claim 1, further comprising a cylindrical inner liner provided between the heating liner and the substrate support and having a height lower than that of the heating liner,
wherein the heating liner is provided with a first exhaust port configured to exhaust the inner space.

8. The substrate processing apparatus of claim 7, further comprising a cylindrical outer liner provided between the inner liner and the heating liner,
wherein the outer liner is provided with a second exhaust port that communicates with the first exhaust port to exhaust the inner space.

9. The substrate processing apparatus of claim 8, wherein the outer liner has an upper inner diameter less than a lower inner diameter thereof.

10. The substrate processing apparatus of claim 1, wherein the substrate support comprises:
a heater configured to heat the substrate;
a heater support flange connected to a lower end of the heater to support the heater; and
a passage which is provided in the heater support flange and through which a temperature control fluid flows.

11. The substrate processing apparatus of claim 10, further comprising:
a bellows connected between a portion of the chamber part and the heater support flange; and
an elastic member provided between the bellows and the heater support flange.

12. The substrate processing apparatus of claim 10, wherein the temperature control fluid is supplied at a temperature higher than room temperature.

13. The substrate processing apparatus of claim 10, wherein the substrate support comprises:
a clamp configured to fix a lower end of the heater to the heater support flange; and
a cover member provided at least partially on the clamp to cover the clamp.

14. The substrate processing apparatus of claim 13, wherein the substrate support further comprises a plate-shaped thermal choke part provided between the clamp and the cover member to suppress heat transfer.

15. The substrate processing apparatus of claim 13, wherein the chamber part has a hole in a central portion of a bottom surface of the chamber part so that a portion of the substrate support passes to move through the hole, and
the substrate processing apparatus further comprises a purge gas supply part configured to supply a purge gas so that the purge gas is ejected through a gap between the hole and the cover member.

16. The substrate processing apparatus of claim 15, wherein the purge gas is provided at a temperature higher than room temperature.
